(19) United States
(12) Patent Application Publication
(10) Pub. No.: US 2017/0191188 A1
(43) Pub. Date: Jul. 6, 2017

(54) CRUCIBLE FOR GROWING CRYSTALS

(71) Applicants: PLANSEE (Shanghai) High Performance Material Ltd., Shanghai (CN); PLANSEE SE, Reutte (AT)

(72) Inventors: Mathias HOCHSTRASSER, Shanghai (CN); David CHENG, Shanghai (CN); Heike LARCHER, Bach (DE); Bernd KLEINPASS, Pfronten (DE); Martin WEBHOFER, Pflach (AT); Wolfgang EBERLE, Heiterwang (AT); Walter HAMMERLE, Reutte (AT)

(21) Appl. No.: 15/323,246

(22) PCT Filed: Jul. 1, 2015
(86) PCT No.: PCT/CN2015/083053

§ 371 Date: Jan. 23, 2017

(30) Foreign Application Priority Data
Jul. 2, 2014 (CN) 201410312751.7

(51) Int. Cl. C30B 35/00; C30B 15/14; C30B 15/10

(52) U.S. Cl. CPC C30B 35/002; C30B 15/10; C30B 15/14; C30B 35/007; C30B 11/002

(57) ABSTRACT

Crucible for growing single crystals, formed from W, Mo, Re, an alloy or a base alloy of these metals, and a process for producing a crucible (2), wherein at least part of an outwardly facing outer face (4) of the crucible (2) has, at least in certain regions, a profile with a mean profile depth (a) of between 5 and 500 μm.

### TECHNICAL FIELD

The invention relates to a crucible for growing crystals, in particular for growing single crystals, formed from W, Mo, Re, an alloy or a base alloy of these metals, and also to a process for producing such a crucible.

### BACKGROUND

The growth of, for example, sapphire single crystals has been undertaken very intensively for a number of years, since single-crystal sapphire substrates in particular are used for the epitaxial deposition of gallium nitride (GaN), which is used widely in turn for producing, for example, LEDs (light emitting diodes) and certain semiconductor lasers.

Various processes for growing single crystals are known. Processes which have become established are, for example, those in which a seed crystal, on the basis of which the single crystal growth is effected, is slowly pulled partially or completely from a molten mass or in which a seed crystal is placed in the bottom region of a crucible and countercooled in a controlled manner, in order to achieve slow solidification from the molten mass. In these processes, use is made of crucibles consisting of high-melting metals, in particular of Mo, W, Re, Ir or alloys of these metals. In order to achieve a single crystal which is free of impurities or defects to the greatest possible extent, it is important to precisely control the supply of heat into the crucible or the molten mass and also the dissipation of heat from the crucible or the molten mass or the single crystal.

### SUMMARY

It is an object of the invention to provide an improved crucible for growing crystals and also a simple process for the production thereof.

This object is achieved by the features of Claim 1 and Claim 12, respectively.

Advantageous embodiments are the subject matter of the dependent claims.

According to Claim 1, provision is made of a crucible for growing crystals, in particular for growing sapphire single crystals. The crucible is produced from W, Mo, Re, an alloy of these metals or a base alloy of these metals. An alloy consisting of W, Mo and/or Re is understood to mean a W—Mo, a W—Re, an Mo—Re or a W—Mo—Re alloy, in which the total content of Mo, W and Re is >95 at %, preferably >98 at %, particularly preferably >99 at % or 99.5 at %. A base alloy comprises alloys which have a proportion of the respective metal of greater than 90 at %, preferably greater than 95 at %, particularly preferably greater than 99 at %. Further alloying elements can be, for example, high-melting oxides, such as for example ZrO₂. At least part of an outwardly facing face (outer face) of the crucible has a profile with, at least in certain regions, a mean profile depth of between 5 and 500 μm, preferably 10 and 300 μm, particularly preferably 15 and 150 μm, 20 and 100 μm or 30 and 80 μm. In the context of the invention, a profile is to be understood as meaning both a profile which has a uniform configuration, for example in the form of scores, or a profile which is configured as a non-uniform structure, for example in the form of a porous layer. By way of example, the exterior side faces of the crucible are provided with said profile at least in certain regions, such that they have a structured surface. The mean profile depth is determined here by way of a conventional contour measuring appliance. To determine the mean profile depth, an average is formed at least over 5 measurement results. If at least 5 recesses are arranged alongside one another, 5 recesses which follow one another directly are used for determining the mean profile depth.

By way of example, the profiles are produced, after the pressing and sintering of a main crucible body, by means of cutting machining, such as e.g. turning, milling, grinding and/or drilling. Alternatively, said profiles can be produced by means of non-cutting machining, such as e.g. laser etching or EDM (electrical discharge machining). The profile can already be produced in this case in the green state of the compacted powder, i.e. before the sintering, by means of suitable processes, such as e.g. turning. The profile is retained during the subsequent sintering. Furthermore, it is possible to produce the profile by way of a coating. Use is preferably made in this case of a porous layer produced by the deposition of a slurry (powder+binder mixture). The layer can be solidified here by way of a separate heat treatment. If the layer is deposited on the compacted material, the solidification can also take place during the sintering.

During the production of a single crystal, a crucible is usually heated from the outside by means of thermal radiation, which is generated by a heating system arranged at a distance from the crucible. A surface profiled in the manner described above has a higher emissivity and a higher degree of absorption than, for example, a smooth, e.g. ground or polished surface. Owing to the structured outer face, the crucible has a high emissivity/degree of absorption. By way of example, if the heating power is reduced, heat is emitted quicker by the crucible, and if the heating power is increased, the heat generated is absorbed quicker by the crucible. Owing to the profiled surface, the crucible reacts quicker to changes in temperature or changes in power of the heating system, such that the temperature and the temperature gradient of the molten mass in the crucible can be precisely regulated. In this way, it is possible to achieve stable, repeatable growth results and therefore a constantly good quality of the single crystals produced using the crucible.

It is preferable that the outer faces of the side walls of the crucible are provided with the profile at least in certain regions. Alternatively, the outer bottom face of the crucible can additionally also be provided with the profile, such that all free outer faces of the crucible which face toward a heating device during the single crystal production have an improved emissivity/degree of absorption.

It is preferable that, at least in certain regions, the profile (in cross section) is in the form of a recess circulating around the crucible or a multiplicity of recesses circulating around the crucible. By way of example, provision is made of a circulating score or groove, this having a thread-like progression and thus being producible in a simple manner by turning. Alternatively, a multiplicity of recesses arranged alongside one another can be provided, e.g. a multiplicity of scores or grooves arranged alongside one another. In addition or as an alternative, provision can be made of a profile with a multiplicity of recesses, in which a multiplicity of recesses arranged alongside one another are formed; by way of example, a multiplicity of blind holes which are arranged alongside one another and are produced by means of milling or drilling, or pores which are produced by way of a porous layer. It is preferable that the (overall) profile or the structure of the outer face of the crucible is formed from a combination of the above-described recesses.

It is preferable that the recesses are distributed uniformly or spaced uniformly apart over the outer face, such that a uniform emissivity/degree of absorption is achieved over the entire outer face.

It is preferable that the recess has, or the multiplicity of recesses have, at least in certain regions, a part-circular, trapezoidal, wedge-shaped and/or rectangular cross section. By way of example, the recess has, or the multiplicity of recesses have, at least in certain regions, a part-circular cross section with a radius of between 0.2 and 10 mm, preferably 0.5 and 8 mm, further preferably 0.6 and 5 mm, particularly preferably 0.8 and 2 mm. The profile or the recesses can be produced by means of a tool, such as e.g. a cutting insert, with the appropriate cutting edge geometry, it being possible for the profile depth to be set easily by way of the cutting depth. Suitable materials for a tool for machining the extremely hard and brittle crucible material are, for example, polycrystalline diamond (PCD) or cubic crystalline boron nitride (CBN).

It is particularly preferable that the mean spacing between adjacent recesses in the axial direction of the crucible is between 0.2 and 10 mm, preferably 0.6 and 5 mm, further preferably 0.7 and 2 mm, particularly preferably 0.8 and 1.5 mm. To determine the mean spacing, an average is again formed using at least 5 measurement results. In the case of 6 recesses in sequence, the mean spacing is determined by averaging the corresponding spacings. By way of example, when producing the profile by means of turning, the spacings can be set easily by appropriately setting the advance—which is indicated in millimetres per revolution—of the tool in the axial direction of the crucible. A (thread-shaped) profile as described above can thus be produced over the entire outer face or side faces of the crucible in one operation or without putting down the tool.

According to a preferred embodiment, an inner face of the crucible facing toward an internal volume has, at least in certain regions, a (radial and axial) mean roughness value Ra of between 0.1 and 1.6 μm, preferably between 0.2 and 0.4 μm. The radial mean roughness value is measured along the inner face radially about a longitudinal axis or axis of symmetry of the crucible, and the axial mean roughness value is measured along the inner face in the direction of the longitudinal axis of the crucible. By way of example, the inner face is ground and/or polished, in particular ground and/or polished axially. It is preferable that the entire inner surface has the aforementioned Ra values.

Owing to the low mean roughness values Ra or the very smooth surface, the interaction between the inner face of the crucible and the molten mass is minimized, and therefore stable and repeatable growth results are achieved. In addition, the low surface tensions on smooth surfaces mean that a reduced level of stresses also arises in the single crystal produced. Owing to the smooth inner face, the rate of material removal from the crucible during the production of single crystals is also reduced, and therefore the service life of a crucible is increased or the crucible can be used repeatedly for growing single crystals. In addition, owing to the low mean roughness value Ra, the inner face of the crucible has a low emissivity. In the (exposed) inner region of the crucible, in which a single crystal has already been produced and which is no longer covered by the molten mass, less heat is irradiated from the inner faces of the crucible onto the single crystal which has already been grown. In contrast thereto, in the region where the molten mass is in contact with the inner face of the crucible, the heat is effectively transmitted into the molten mass by means of heat conduction. This effect is particularly advantageous in the case of various production processes, such as e.g. the Czochralski process or the Nacken-Kyropoulus process, in which the single crystal which has already been produced (or the seed crystal) has to be cooled in order to precisely control the temperature gradient of the single crystal produced. This is ensured by the above-described inner face of the crucible. A further important advantage consists in the fact that a rough surface promotes the crystal nucleation, which by nature is undesirable in the case of a single crystal pulling process.

According to Claim 12, provision is made of a process for producing a crucible for growing crystals, in particular a crucible as described above. Firstly, a pressed main crucible body or alternatively a pressed and sintered main crucible body or alternatively a pressed, sintered and deformed (for example by flow forming) main crucible body or alternatively a main crucible body produced by a coating process (e.g. CVD, powder spraying) is provided, said main crucible body consisting of W, Mo, Re, an alloy of these metals or a base alloy of these metals, wherein the total content of Mo, W and Re is >95 at %, preferably >98 at %, particularly preferably >99 at % or 99.5 at %. A base alloy comprises alloys which have a proportion of the respective element or metal of greater than 90 at %, preferably greater than 95 at %, particularly preferably greater than 99 at %. Further alloying elements can be high-melting oxides, for example. Then, the outer face of the main crucible body is machined, such that at least part of the outer face has, at least in certain regions, a profile with a profile depth of between 5 and 500 μm, preferably 10 and 300 μm, particularly preferably 15 and 150 μm, 20 and 100 μm or 30 and 80 μm. By way of example, the outer face of the main crucible body is machined by means of cutting machining processes, such as e.g. turning, milling and/or drilling.

It is preferable that an inner face of the crucible or of the main crucible body facing toward an internal volume is machined, such that the inner face has a (radial and axial) mean roughness value Ra of between 0.1 and 1.6 μm, preferably 0.2 and 0.3 μm. By way of example, the inner face is machined by means of axial grinding and/or polishing.

The above-described advantages are achieved by the treatment according to the invention of the outer face and inner face. All of the features described above in conjunction with the crucible can be combined as desired with the process for producing such a crucible.

### BRIEF DESCRIPTION OF THE FIGURES

Embodiments of the invention will be explained in more detail with reference to the figures.

FIG. 1 shows a schematic sectional view, not true to scale, of a crucible during the production of a single crystal.

FIGS. 2a-2b show schematic illustrations, not true to scale, of an outer face and inner face of the crucible shown in FIG. 1.

FIG. 3 shows the result of a contour measurement.

### DETAILED DESCRIPTION

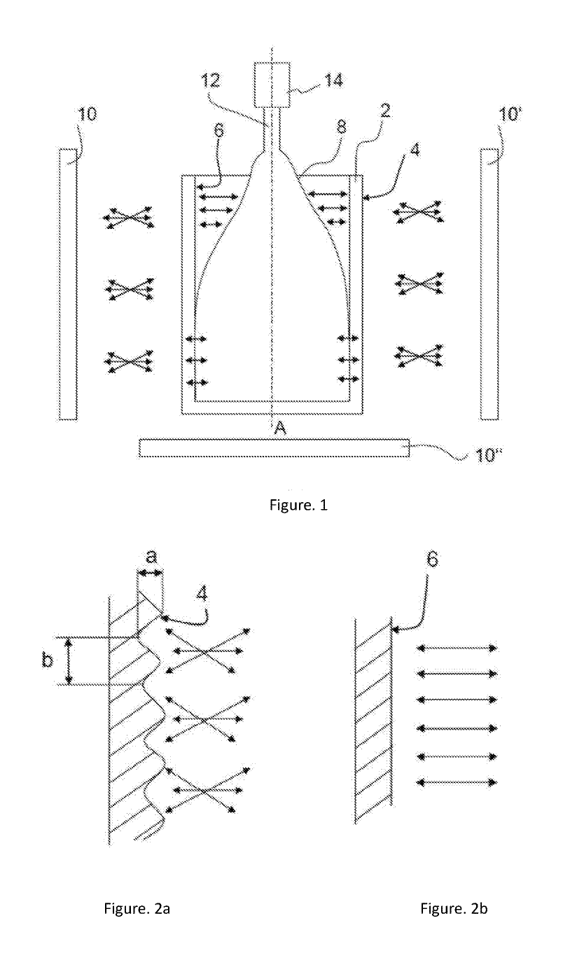

FIG. 1 shows a schematic sectional view, not true to scale, of a crucible 2 during the production of a single crystal. The crucible 2 is produced from W, Mo, Re or an alloy of these materials, in order to withstand the high temperatures during the production of a single crystal, such as e.g. a sapphire single crystal.

The schematically illustrated crucible 2 is designed so as to be rotationally symmetrical about its axis A, e.g. cylindrical or substantially cylindrical. The crucible 2 can have a conical form, in order to facilitate the removal of a single crystal 8 produced therein. The outer dimensions of the crucible 2 can be adapted to the desired size of the single crystal to be produced. By way of example, 2 sapphire single crystals with a weight of 30 kg, 60 kg, 90 kg, 120 kg or more can be produced with an appropriate crucible. By way of example, a crucible 2 can have a diameter of 500 mm and a height of approximately 600 mm.

The schematically illustrated side wall heating systems 10, 10′ and bottom heating system 10″ are intended to illustrate the heating of the crucible 2 by means of thermal radiation. A seed crystal 12, on the basis of which the single crystal growth is effected, is illustrated in sketched form above the crucible 2. The seed crystal 12 is held in a seed crystal holder 14 and, for producing the single crystal, is pulled slowly from a molten mass (Al₂O₃ in the case of sapphire single crystals) in the crucible 2. Shown adjoining the seed crystal 12 is a single crystal 8, which has already been pulled from the molten mass in the lower region of the crucible 2. As is shown schematically here, it is possible to use, for example, the Nacken-Kyropoulus process or the Czochralski process, in which a seed crystal 12 is dipped from above into the molten mass. Alternatively (not shown), a seed crystal can be placed in the bottom region of the crucible 2 and countercooled in a controlled manner, in order to achieve slow solidification from the molten mass.

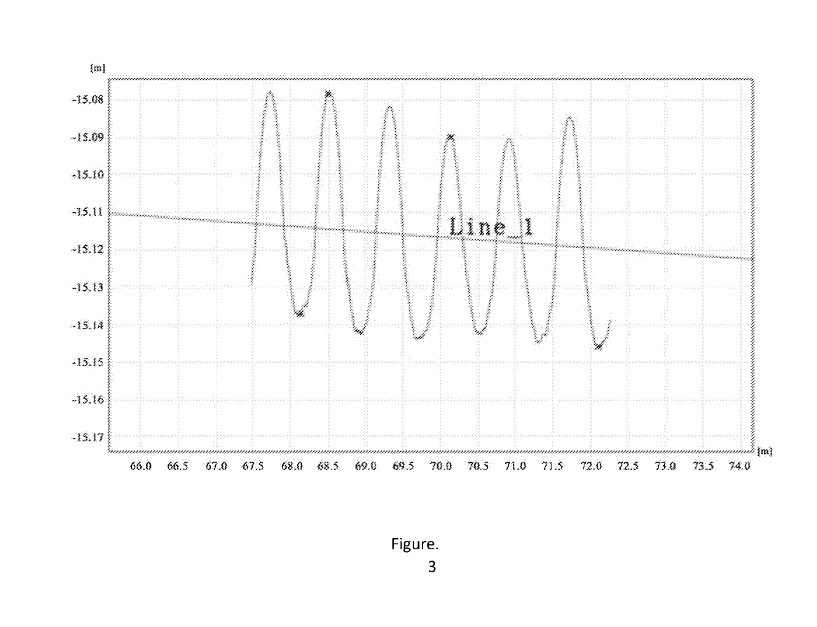

The outer face 4 or side faces of the crucible 2 have a profile, which is shown on an enlarged scale and by way of example in FIG. 2a. The profile or the surface structure has a mean profile depth a of between 5 and 500 μm, 10 and 300 μm, 15 and 150 μm, 20 and 100 μm or 30 and 80 μm. The profile depth is measured here using a contour measuring appliance, for example a Mitutoyo Formtracer SV-C3200. The reference points for a recess are formed here by two elevations and a recess enclosed thereby. To determine the mean profile depth a, an average is formed at least over 5 measurement results. As is shown in FIG. 2a, the profile can be formed from a multiplicity of recesses which are arranged alongside one another and have the aforementioned profile depth. If at least 5 recesses are arranged alongside one another, 5 recesses which follow one another directly are used for determining the mean profile depth a. The result of an exemplary contour measurement is shown in FIG. 3. Here, the mean value of at least 5 elevations which follow one another directly is calculated, and the mean profile depth is thus determined.

The profile or the structure of the outer face 4 can be produced easily by means of turning or milling, for example. A profile with a thread-like progression can be produced easily and quickly in a turning operation using an appropriately shaped tool, with an appropriately set cutting depth and an appropriately set advance (millimetres per revolution). By way of example, the recesses have a conical, wedge-shaped, trapezoidal, part-circular or rectangular cross section, it being possible for the cross-sectional shape to be established easily, for example, via the selection of the appropriate tool or the cutting edge shape of the tool. According to one example, the thread-like profile has a recess with a part-circular cross section with a mean radius of between 0.2 and 10 mm, 0.6 and 5 mm or 0.8 and 2 mm. To determine the mean radius, an average is again formed over at least 5 measurement results.

The mean spacing between adjacent recesses in the axial direction of the crucible 2 can be between 0.2 and 10 mm, 0.5 and 8 mm, 0.6 and 5 mm, 0.7 and 2 mm or 0.8 and 1.5 mm. During the production, an advance of 0.2 to 10 mm per revolution, 0.5 to 8 mm per revolution, 0.6 to 5 mm per revolution or 0.7 to 2 mm per revolution is set. To determine the mean spacing, too, at least 5 measurement results are used in turn.

Suitable materials for machining the extremely hard and brittle crucible material are, for example, tools with cutting edges made from polycrystalline diamond (PCD) or cubic crystalline boron nitride (CBN).

The inner face 6 of the crucible 2, in contrast to the outer face 4, has a very smooth form, such that the inner face 6 has, at least in certain regions, a (radial and axial) mean roughness value Ra of between 0.1 and 1.6 μm, 0.1 and 1 μm or 0.2 and 0.3 μm. By way of example, the inner face 6 is ground axially. In addition, the inner face 6 can be polished in the axial direction of the crucible 2 in order to produce a particularly smooth surface.

Owing to the profile, the outer face of the crucible 2 has—compared to a smooth face—a high emissivity and degree of absorption. The emitted or absorbed thermal radiation of the rough outer face 4 compared to the smooth inner face 6 of the crucible is shown in qualitative terms by means of arrows in FIGS. 2a-b.

Owing to the high emissivity/degree of absorption of the outer face 4, if the heating power is reduced, heat is emitted quicker by the crucible 2, and if the heating power is increased, the heat generated is absorbed quicker by the crucible 2. Owing to the profiled or rough surface, the crucible 2 therefore reacts quicker to changes in temperature or changes in power of the heating system 10, 10′, such that the temperature and the temperature gradient of the single crystal 8 in the crucible 2 can be precisely regulated. In this way, it is possible to achieve stable, repeatable growth results or a constantly good quality of the single crystals 8 produced using the crucible 2.

Compared to the rough outer face 4, the very smooth inner face 6 has only a low emissivity and degree of absorption. Therefore, only little heat is irradiated onto the single crystal 8 via the inner face 6 in the upper region of the crucible 2, where a single crystal 8 has already been grown and which is not in contact with the inner face 4 of the crucible 2. In the lower region of the crucible 2, where the molten mass is in contact with the inner face 6 or the crucible wall, heat is efficiently transmitted from the crucible 2 onto the molten mass by means of heat conduction. As a result, it is possible to efficiently control the temperature gradient in the single crystal 8 produced. This is particularly advantageous for the production of a single crystal by means of the Nacken-Kyropoulus process, in which the temperature or the temperature gradient of the single crystal and of the molten mass has to be precisely controlled.

### LIST OF REFERENCE SIGNS

2 Crucible
4 Outer face
6 Inner face
8 Single crystal/ingot
10, 10′, 10″ Heating system
12 Seed crystal
14 Seed crystal holder
A Crucible axis
a Profile depth
b Spacing/advance

1. Crucible for growing crystals, in particular for growing single crystals, formed from W, Mo, Re, an alloy or a base alloy of these metals,
wherein an outer face of the crucible has, at least in certain regions, a profile with a mean profile depth between 5 and 500 μm.

2. Crucible according to claim 1, wherein the profile has a mean profile depth (a) of between 10 and 300 μm.

3. Crucible according to claim 1, wherein the profile has a recess or a multiplicity of recesses, which are arranged spaced uniformly apart at least in certain regions over the outer face of the crucible.

4. Crucible according to claim 1, wherein the profile is in the form of a recess circulating around the crucible (2), in particular a score or groove, or a multiplicity of recesses circulating around the crucible (2).

5. Crucible according to claim 1, wherein the profile has a recess or a multiplicity of recesses with a part-circular, trapezoidal, wedge-shaped, conical and/or rectangular cross section.

6. Crucible according to claim 1, wherein the profile, at least in certain regions, has a recess or a multiplicity of recesses with a part-circular cross section with a radius of between 0.2 and 10 mm.

7. Crucible according to claim 1, wherein the profile has a recess or a multiplicity of recesses with, at least in certain regions, a part-circular cross section with a radius of between 0.8 and 6 mm.

8. Crucible according to claim 1, wherein the profile has a multiplicity of recesses and the mean spacing between adjacent recesses in the axial direction of the crucible is, at least in certain regions, between 0.2 and 10 mm.

9. Crucible according to claim 1, wherein the profile has a multiplicity of recesses and the spacing between adjacent recesses in the axial direction of the crucible is, at least in certain regions, between 0.8 and 6 mm.

10. Crucible according to claim 1, wherein the outer faces of the crucible which are exposed during the production of a single crystal have the profile, in particular the side walls of the crucible.

11. Crucible according to claim 1, wherein an inner face of the crucible facing toward an internal volume has, at least in certain regions, a mean roughness value Ra of between 0.1 and 1.6 μm, in particular is ground axially and/or polished axially.

12. Process for producing a crucible for growing crystals, in particular a crucible according to claim 1, said process comprising the following steps:
providing a pressed main crucible body, a pressed and sintered main crucible body, a pressed, sintered and deformed main crucible body or a main crucible body produced by way of a coating process, including machining or coating an outer face of the main crucible body, such that at least part of the outer face has a profile with, at least in certain regions, a mean profile depth of between 5 and 500 μm.

13. Process according to claim 12, further comprising the following step: machining an inner face of the crucible facing toward an internal volume, such that the inner face has, at least in certain regions, a mean roughness value Ra of between 0.1 and 1.6 μm.
